(19) United States
(12) Patent Application Publication
(10) Pub. No.: US 2015/0156880 A1
(43) Pub. Date: Jun. 4, 2015

(54) PRINTED WIRING BOARD AND METHOD FOR MANUFACTURING PRINTED WIRING BOARD

(71) Applicant: IBIDEN CO., LTD., Ogaki-shi (JP)

(72) Inventor: Tomoya DAIZO, Ogaki-shi (JP)

(73) Assignee: IBIDEN CO., LTD., Ogaki-shi (JP)

(21) Appl. No.: 14/555,840

(22) Filed: Nov. 28, 2014

(30) Foreign Application Priority Data
Nov. 29, 2013 (JP) 2013-247467

(51) Int. Cl. H05K 1/18; B23K 26/40; H05K 3/06; H05K 1/11; H05K 3/18; H05K 3/40; H05K 1/02; H05K 1/03; B23K 26/38; H05K 3/02

(52) U.S. Cl. CPC H05K 1/183; B23K 26/38; B23K 26/4095; H05K 3/06; H05K 3/027; H05K 3/184; H05K 3/4007; H05K 1/0298; H05K 1/0313; H05K 1/113

(57) ABSTRACT

A printed wiring board includes a core substrate, a first build-up layer formed on first surface of the substrate and having a recess formed to accommodate an electronic component, a second build-up layer formed on second surface of the substrate, and multiple pads including first pads on the first layer, second pads on the second layer, and third pads in bottom surface of the recess. The first and second layers have interlayer insulating layers, the insulating layers in interior portion of the first layer between the substrate and the bottom surface of the recess has number of insulating layers equal to number of insulating layers in the second layer, and the insulating layers in exterior portion of the first layer between the core substrate and the surface of the first layer has number of insulating layers greater than number of insulating layers in the second layer.

### CROSS-REFERENCE TO RELATED APPLICATIONS

The present application is based upon and claims the benefit of priority to Japanese Patent Application No. 2013-247467, filed Nov. 29, 2013, the entire contents of which are incorporated herein by reference.

### BACKGROUND OF THE INVENTION

1. Field of the Invention

The present invention relates to a printed wiring board and a method for manufacturing a printed wiring board, the printed wiring board accommodating an electronic component in a cavity provided to a resin insulating layer and connecting to a superstrate to which the electronic component is mounted.

2. Description of Background Art

Japanese Patent Laid-open Publication No. 2010-245530 describes a printed wiring board having a core substrate and a build-up layer on both surfaces thereof, the printed wiring board further including a cavity for housing an electronic component in one of the build-up layers. A number of build-up layers on the two surfaces is equal at two layers, and the cavity is formed by providing an opening in one of the build-up layers so as to expose the core substrate. The entire contents of this publication are incorporated herein by reference.

### SUMMARY OF THE INVENTION

According to one aspect of the present invention, a printed wiring board includes a core substrate, a first build-up layer formed on a first surface of the core substrate and having a recessed portion formed to accommodate an electronic component, a second build-up layer formed on a second surface of the core substrate on the opposite side with respect to the first surface of the core substrate, and multiple contact pads including first contact pads formed on a surface of the first build-up layer, second contact pads formed on a surface of the second build-up layer, and third contact pads formed in a bottom surface of the recessed portion of the first build-up layer. The first build-up layer has interlayer insulating layers, the second build-up layer has interlayer insulating layers, the interlayer insulating layers in an interior portion of the first build-up layer between the core substrate and the bottom surface of the recessed portion have a number of interlayer insulating layers which is equal to a number of interlayer insulating layers in the second build-up layer, and the interlayer insulating layers in an exterior portion of the first build-up layer between the core substrate and the surface of the first build-up layer have a number of interlayer insulating layers which is greater than a number of interlayer insulating layers in the second build-up layer.

According to another aspect of the present invention, a method for manufacturing a printed wiring board includes forming a first build-up layer including one or more interlayer insulating layers on a first surface of a core substrate, forming a second build-up layer including one or more interlayer insulating layers on a second surface of the core substrate on the opposite side with respect to the first surface of the core substrate such that the second build-up layer has a number of the interlayer insulating layer or layers which is equal to a number of the interlayer insulating layer or layers in the first build-up layer, forming a laser reception conductor pattern on a surface of the first build-up layer such that the first build-up layer includes the laser reception conductor pattern extending along an edge of a recessed portion formation position, forming a peel layer on the recessed portion formation position on the first build-up layer such that the first build-up layer includes the peel layer, forming a resin insulating layer around the periphery of a peel layer such that the first build-up layer includes the resin insulating layer having an opening corresponding to the peel layer, forming the outermost-tier resin insulating layer on the opening of the resin insulating layer and the resin insulating layer such that the first build-up layer includes the outermost-tier resin insulating layer, irradiating laser upon the first build-up layer such that a slit reaching to the laser reception conductor pattern is formed, and removing the peel layer from the first build-up layer such that a recessed portion formed to accommodate an electronic component is formed in the first build-up layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a printed wiring board according to a first embodiment of the present invention;

FIG. 2(A)-2(D) illustrate a step diagram for a method for manufacturing the printed wiring board according to the first embodiment;

FIG. 3(A)-3(D) illustrate a step diagram for the method for manufacturing the printed wiring board according to the first embodiment;

FIG. 4(A)-4(B) illustrate a step diagram for the method for manufacturing the printed wiring board according to the first embodiment;

FIG. 5(A)-5(C) illustrate a step diagram for the method for manufacturing the printed wiring board according to the first embodiment;

FIG. 6(A)-6(C) illustrate a step diagram for the method for manufacturing the printed wiring board according to the first embodiment;

FIG. 7(A)-7(B) illustrate a step diagram for the method for manufacturing the printed wiring board according to the first embodiment;

FIG. 8(A)-8(B) illustrate a step diagram for the method for manufacturing the printed wiring board according to the first embodiment;

FIG. 9 is a plan view of the printed wiring board according to the first embodiment; and

FIG. 10 is a cross-sectional view illustrating an exemplary application of the printed wiring board according to the first embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

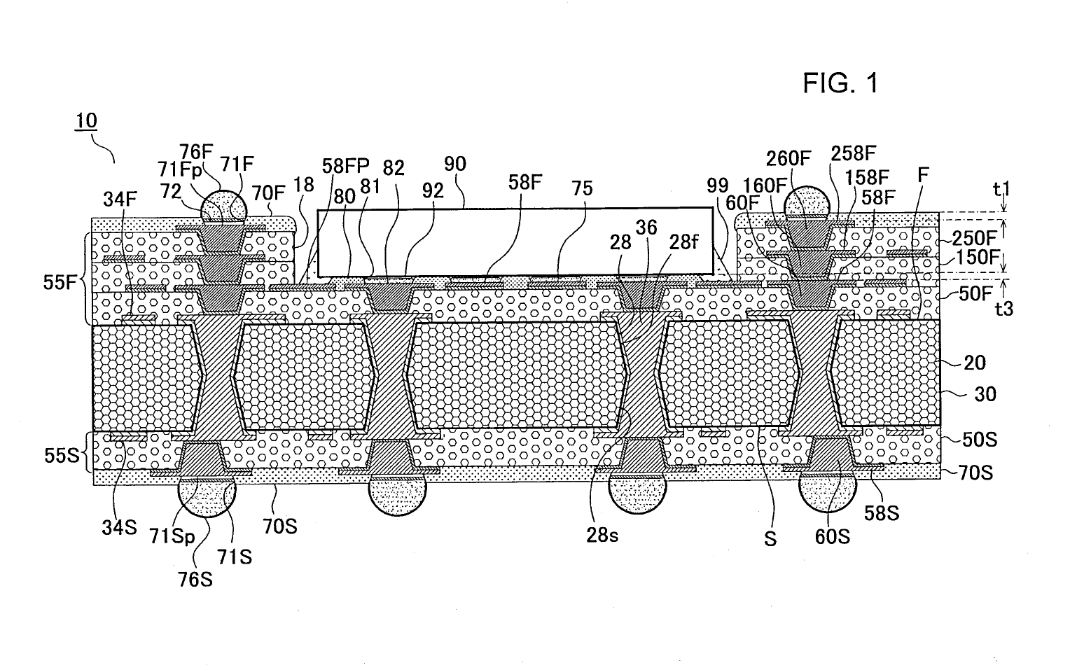

A first printed wiring board 10, structuring a printed wiring board according to the first embodiment, is shown in cross-section in FIG. 1. The first printed wiring board 10 includes a core substrate 30 formed by an insulating substrate 20 having a first surface (F) and a second surface (S) on a side opposite the first surface (F); a first conductor layer (34F) on the first surface of the insulating substrate; a second conductor layer (34S) on the second surface of the insulating substrate; and a through-hole conductor 36 in contact with the first conductor layer (34F) and the second conductor layer (34S). The core substrate includes the first surface (F) and the second surface on the side opposite the first surface (F). The first surface of the core substrate is the same surface as the first surface of the insulating substrate, and the second surface of the core substrate is the same surface as the second surface of the insulating substrate.

The through-hole conductor 36 is formed by filling a through-hole 28 in the insulating substrate with a plating film. The through-hole 28 is formed by a first opening 28f), formed on the first surface side of the insulating substrate, and a second opening (28s, formed on the second surface side. The first opening (28f) tapers from the first surface toward the second surface. The second opening (28s) tapers from the second surface toward the first surface. In addition, the first opening (28f) and the second opening (28s) connect to each other on an interior of the insulating substrate.

A first build-up layer (55F) is formed on the first surface (F) of the core substrate 30. The build-up layer (55F) has a low-tier resin insulating layer (50F) formed on the core substrate and the first conductor layer (34F). A conductor layer (58F) is formed on the low-tier resin insulating layer (50F). The conductor layer (58F) and the first conductor layer (34F) are connected by a via conductor (60F) running through the low-tier resin insulating layer (50F). A mid-tier resin insulating layer (150F) is formed on the low-tier resin insulating layer (50F). A conductor layer (158F) is formed on the mid-tier resin insulating layer (150F). The conductor layer (158F) and the conductor layer (58F) are connected by a via conductor (160F) running through the mid-tier resin insulating layer (150F). An outermost-tier resin insulating layer (250F) is formed on the mid-tier resin insulating layer (150F). A conductor layer (258F) is formed on the outermost-tier resin insulating layer (250F). The conductor layer (258F) and the conductor layer (158F) are connected by a via conductor (260F) running through the outermost-tier resin insulating layer (250F). The first build-up layer (55F) is formed by the three tiers of resin insulating layers (50F, 150F, 250F). However, the first build-up layer (55F) is not limited to this, and may instead has two layers, or four or more layers.

A second build-up layer (55S) is formed on the second surface (S) of the core substrate 30. The build-up layer (55S) has a resin insulating layer (50S) formed on the core substrate and the second conductor layer (34S). A conductor layer (58S) is formed on the resin insulating layer (50S). The conductor layer (58S) and the second conductor layer (34S) are connected by a via conductor (60S) running through the resin insulating layer (50S). The second build-up layer (55S) is formed by a single tier of the resin insulating layer (50S). However, the second build-up layer (55S) is not limited to this, and may instead has two or more layers.

A first solder resist layer (70F) is formed on the first build-up layer (55F), and a second solder resist layer (70S) is formed on the second build-up layer (55S). The solder resist layer (70F) includes a first opening (71F) exposing a first pad (71Fp). The solder resist layer (70S) includes a second opening (71S) exposing a second pad (71Sp).

Connecting members (76F, 76S) such as solder bumps or an Sn film, are formed on the first pad (71 Fp) and the second pad (71 Sp) to connect to an electronic component or motherboard. The connecting members may also be omitted.

A cavity 18 is formed in the first build-up layer (55F), the cavity 18 being formed by an opening 18 running through the outermost-tier resin insulating layer (250F) and the mid-tier resin insulating layer (150F). An electronic component 90 is accommodated in the cavity 18. In the first embodiment, the electronic component is a logic chip, such as a CPU. In addition to an IC chip, such as a CPU or memory, and an active component, a passive component can also be accommodated in the first embodiment. The conductor layer (58F), which is exposed through an opening 81 in a third solder resist layer 80 formed on the low-tier resin insulating layer (50F), forms a third pad 82 connected to a terminal 92 of the electronic component. A solder bump 75 is formed on the third pad 82. A laser reception conductor pattern (58FP) is formed on a bottom surface of the cavity 18, along an outer edge thereof A lower portion of the electronic component 90 is filled in by an underfill 99.

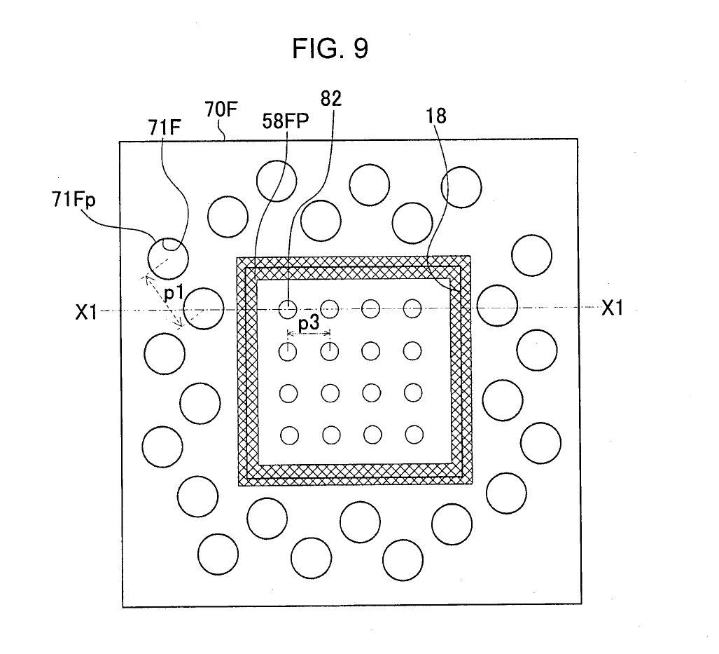

FIG. 9 is a plan view of the printed wiring board 10 prior to formation of the connecting members and prior to mounting of the electronic component. FIG. 1 corresponds to a cross-section of FIG. 9 along line X1-X1.

The third pad 82 is formed on the bottom of the cavity 18, and the first pad (71F) is exposed from the first solder resist layer (70F) on the first build-up layer. The laser reception conductor pattern (58FP) is arranged along the outer edge of the cavity 18 such that an inner side of the laser reception conductor pattern (58FP) is exposed and an outer side is buried in the build-up layer.

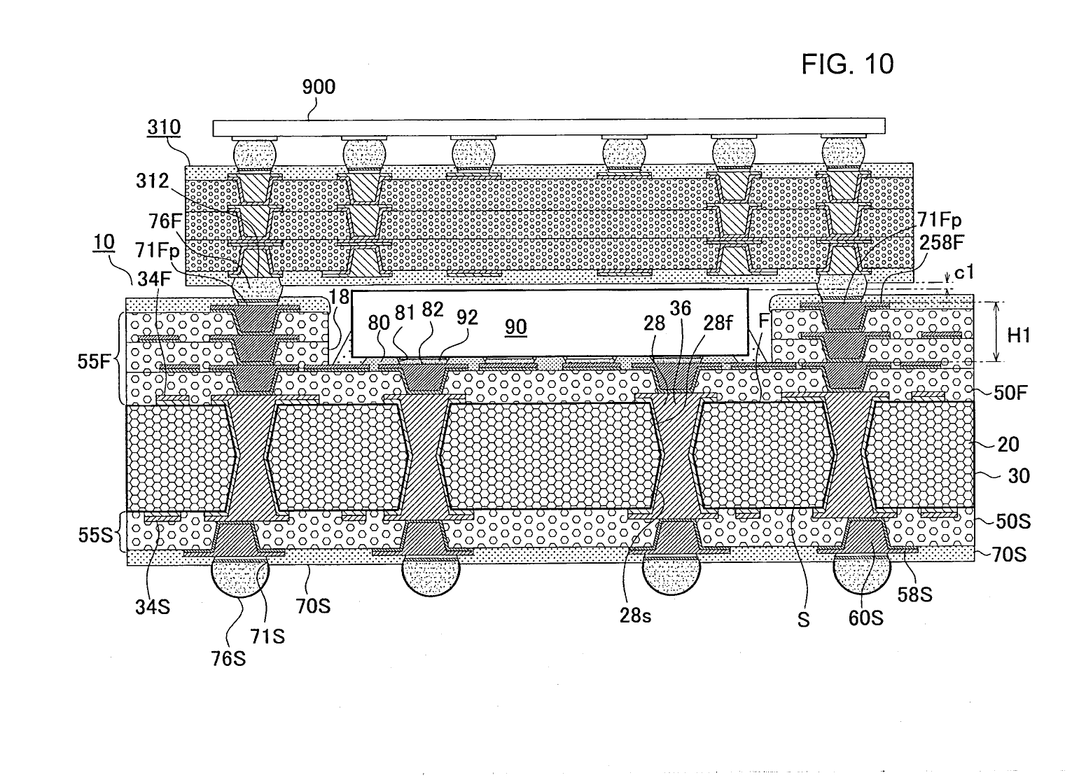

FIG. 10 is a cross-sectional view of the printed wiring board 10 having a superstrate 310 mounted thereon. The superstrate 310 has an IC chip 900 (e.g., memory) mounted on it. The superstrate 310 is connected to the printed wiring board 10 via a pad 312, the first pad (71Fp), and a solder bump (76F).

As shown in FIG. 1, a thickness (t1) of the first solder resist layer (70F) is between 20 μm and 30 μm, and a thickness (t3) of the third solder resist layer 80 is between 12 and 18 μm, with the first solder resist layer (70F) being longer. The third solder resist layer 80 is thin, and therefore the third pad 82 can be arranged at a fine pitch. As shown in FIG. 10, a top surface of the first connection pad (71Fp) is positioned higher than the top surface of the third connection pad 92, at a height (H1) between 80 μm and 250 μm. Thereby, an electronic component having a thickness between 100 μm and 270 μm can be accommodated within the cavity 18 while maintaining a minimum clearance (c1) of 30 to 100 μm from the superstrate 310 to enable heat release.

The printed wiring board according to the first embodiment has, across an interior of the cavity 18, a number of interlayer insulating layers in the first build-up layer (55F) equal to the number of interlayer insulating layers in the second build-up layer (55S). When the number of layers in the build-up layers is symmetrical across the interior (bottom) of the recessed portion and the interlayer insulating layers are cured, stress is applied symmetrically, and therefore coplanarity of the cavity bottom is favorable and reliability of a connection between the fine pitch terminals 92 of the electronic component 90 accommodated therein and the third pads 82 provided to the cavity bottom improves. Moreover, the number of interlayer insulating layers in the first build-up layer (55F) is greater than the number of interlayer insulating layers in the second build-up layer (55S) on an exterior of the recessed portion. Therefore, an area where a top end of the first surface-side build-up layer connects with the superstrate side is raised by the amount (H1), the diameter of the solder bump (76F) can be reduced, and connections between the first pads (71Fp) and the superstrate pads 312 can be achieved at a narrow pitch (p1) (see FIG. 9).

A pitch (distance between centers of neighboring pads) (p3) of the third pads 82 is narrower than the pitch (p1) of the first pads (71Fp). Therefore, the interior of the recessed portion (across the bottom of the recessed portion), where the third pads are provided requires more favorable coplanarity than the exterior of the recessed portion, where the first pads (71Fp) are provided.

Method for Manufacturing Printed Wiring Board according to First Embodiment

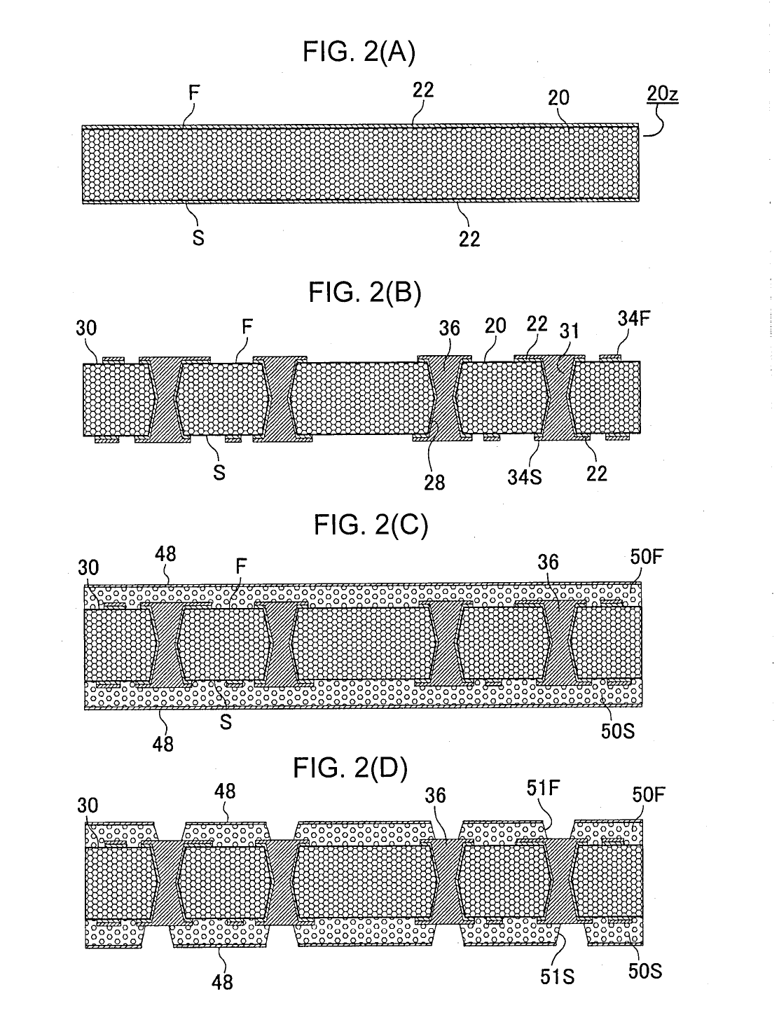

A method for manufacturing the printed wiring board 10 according to the first embodiment is shown in FIGS. 2 to 11.

(1) The insulating substrate 20 having the first surface (F) and the second surface (S) on the side opposite the first surface and a copper-clad laminate (20z) formed by copper foil 22 laminated on both surfaces thereof are prepared (FIG. 2(A)).

The insulating layer of the insulating substrate 20 is formed with resin and a reinforcement material, examples of which reinforcement material may include glass fiber cloth, aramid fiber, and glass fiber. Examples of the resin may include epoxy resin and BT (bismaleimide triazine) resin.

(2) The through-hole conductor 36, the first conductor layer (34F), and the second conductor layer (34S) are formed on the insulating substrate 20 using a method described in U.S. Pat. No. 7,786,390, completing the core substrate 30 (FIG. 2(B)). The entire contents of this publication are incorporated herein by reference.

(3) A resin insulating layer, formed by impregnating inorganic fibers on the first surface and the second surface of the core substrate 30 with resin containing inorganic filler, and copper foil 48 are laminated, then the low-tier resin insulating layers (50F, 50S) are formed by hot-pressing (FIG. 2(C)). Herein, the resin insulating layer (50S) can also employ an insulating layer formed by inorganic filler and resin.

(4) Using a CO₂ gas laser, a via conductor opening (51F) is formed on the low-tier resin insulating layer (50F) and a via conductor opening (51S) is formed on the resin insulating layer (50S) (FIG. 2(D)).

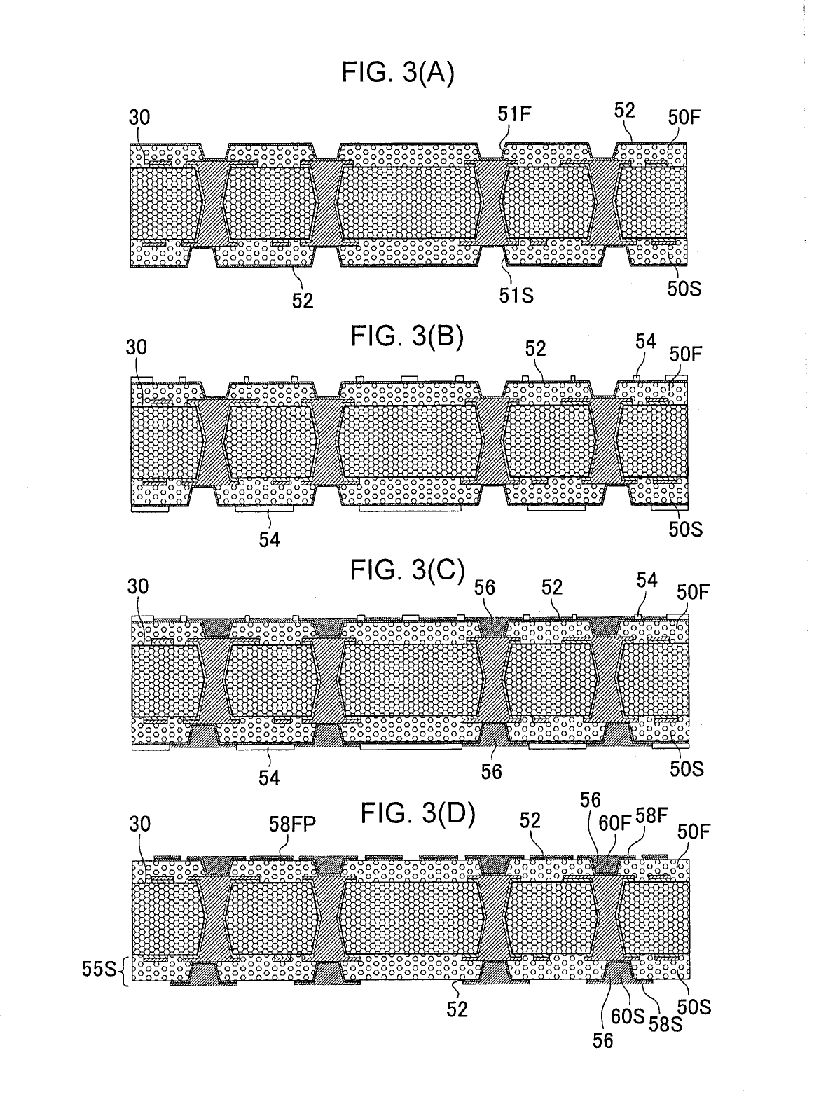

(5) An electroless copper plating layer 52 is formed on a front surface of the interlayer resin insulating layers and on inner walls of the openings (51F, 51S) (FIG. 3(A)).

(6) A plating resist 54 is formed on the electroless copper plating layer 52 (FIG. 3(B)).

(7) A copper electroplating layer 56 is formed on the electroless copper plating layer 52 exposed via the plating resist 54 (FIG. 3(C)).

(8) The plating resist 54 is removed. The electroless copper plating layer 52 between the copper electroplating layers 56 is removed by etching, thereby forming the conductor layers (58F, 58S) and the via conductors (60F, 60S) (FIG. 3(D)). At this point, the laser reception conductor pattern (58FP) shown in FIG. 9 is formed. The second build-up layer (55S) is complete.

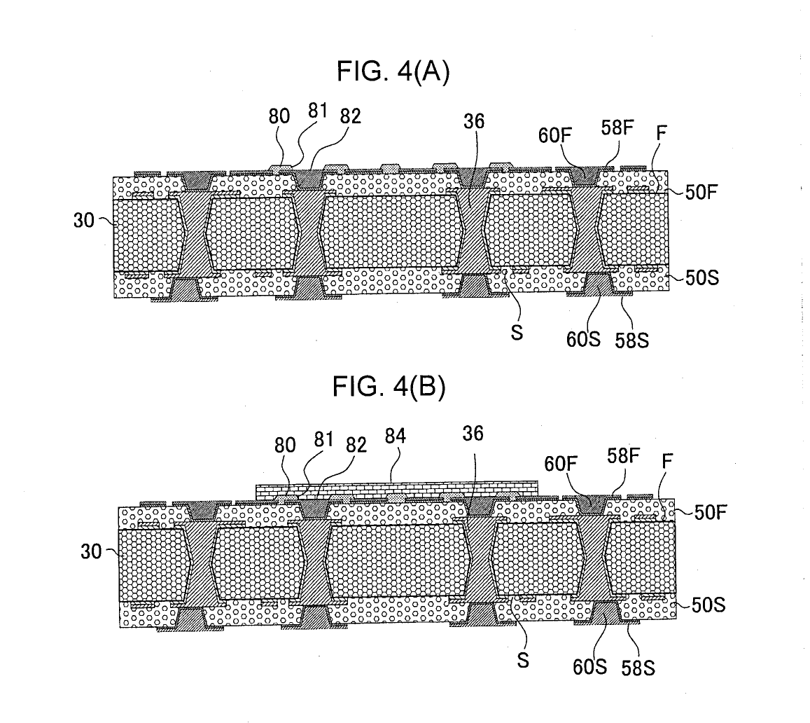

(9) The third solder resist layer 80, which includes the third opening 81, is formed at a cavity formation location on the low-tier resin insulating layer (50F) and the conductor layer (58F) (FIG. 4(A)). The conductor layer exposed via the third opening 81 forms the third pad 82.

(10) A peel layer 84 is formed at the cavity formation location on the third solder resist layer 80 (FIG. 4(B)).

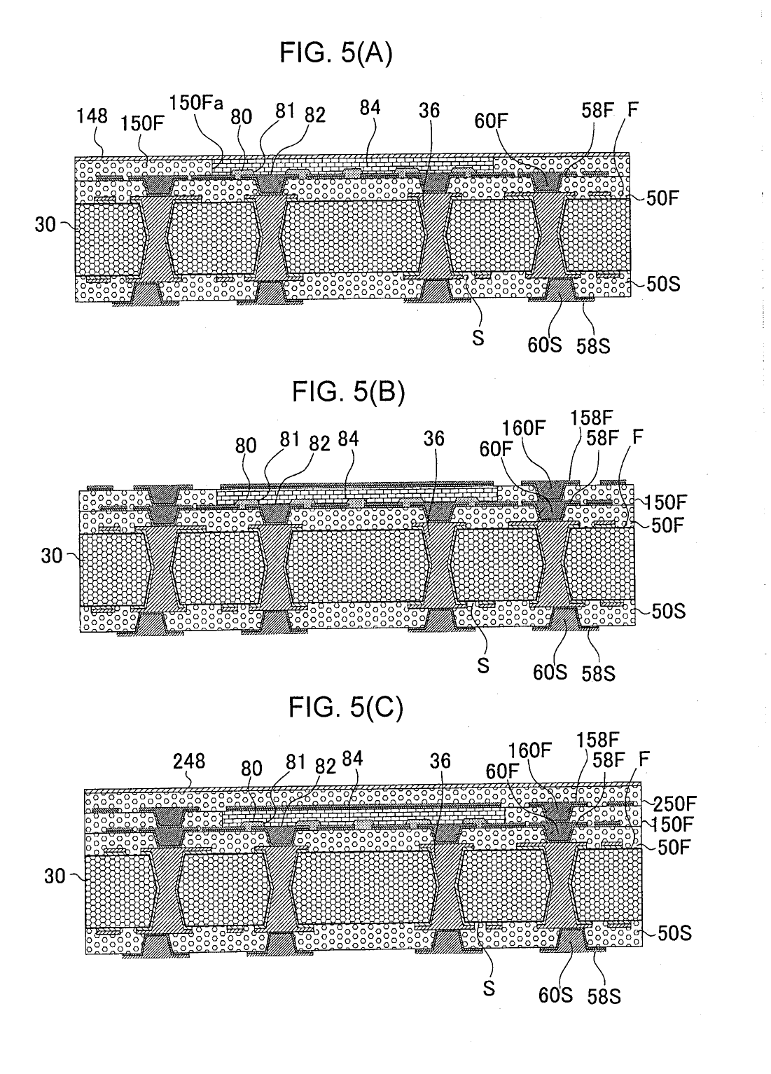

(11) A resin insulating layer (150F) is formed around a periphery of the peel layer 84 such that the resin insulating layer (150F) has an opening (150Fa) corresponding to the peel layer 84, and copper foil 148 is laminated onto the peel layer 84 and the resin insulating layer (150F), then the mid-tier resin insulating layer (150F) is formed by hot-pressing (FIG. 5(A)).

(12) The steps shown in FIG. 3(A) to 3(D) are repeated, forming the conductor layer (158F) and the via conductor (160F), which connects the conductor layer (158F) to the lower conductor layer (58F) (FIG. 5(B)).

(13) A resin insulating layer and copper foil 248 are laminated onto the mid-tier resin insulating layer (150F) and the conductor layer (158F), then the outermost-tier resin insulating layer (250F) is formed by hot-pressing (FIG. 5(C)).

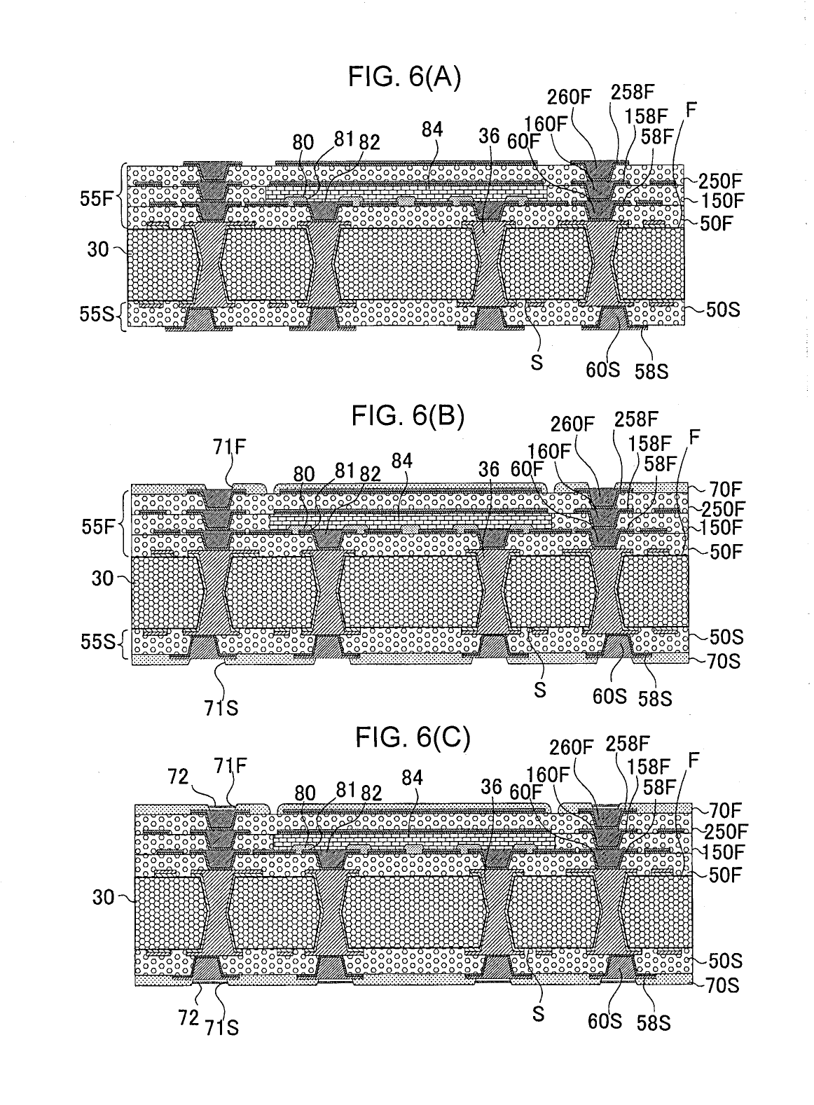

(14) The steps shown in FIG. 3(A) to 3(D) are repeated, forming the conductor layer (258F) and the via conductor (260F), which connects the conductor layer (258F) to the lower conductor layer (158F), completing the first build-up layer (55F) (FIG. 6(A)).

(15) The solder resist layer (70F), provided with the opening (71F), is formed on the first build-up layer (55F), and the solder resist layer (70S), provided with the opening (71S), is formed on the second build-up layer (55S) (FIG. 6(B)).

(16) A surface treatment film 72 is formed on the first pad (71Fp), which is exposed through the opening (71F) of the first solder resist layer (70F), and on the second pad (71Sp), which is exposed through the opening (71S) of the second solder resist layer (70S) (FIG. 6(C)). The surface treatment film is formed by nickel-gold (Ni/Au), Sn plating, a nickel-palladium-gold layer (Ni/Pd/Au), Pd/Ag plating, or an OSP (Organic Solderability Preservative) film.

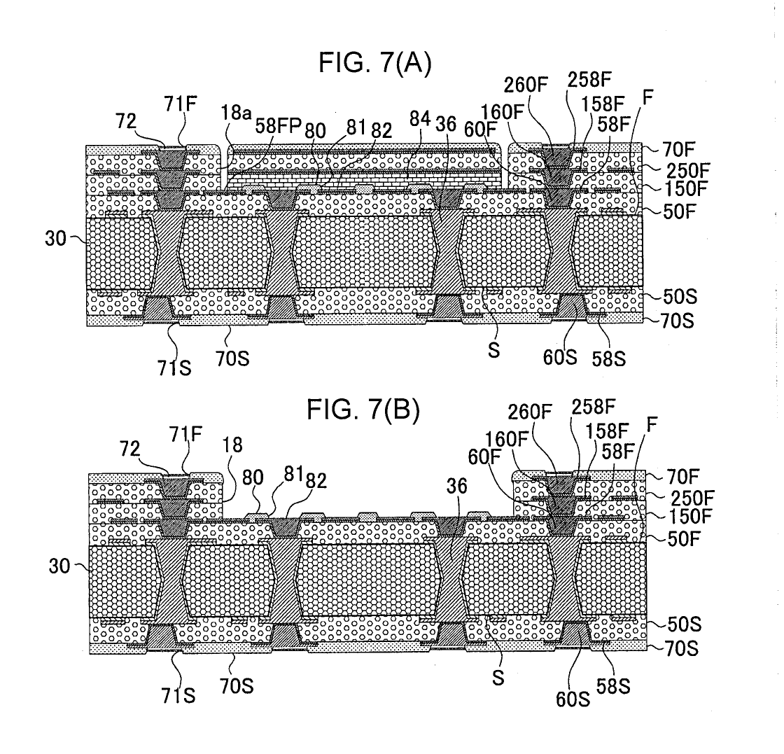

(17) Using a laser, a slit (18a) is formed in the outermost-tier resin insulating layer (250F), the peel layer 84, and the mid-tier resin insulating layer (150F), the slit reaching the laser reception conductor pattern (58FP) (FIG. 7(A)), then the sliced resin insulating layer (250F) and peel layer 84 are removed and the cavity 18 is formed (FIG. 7(B)).

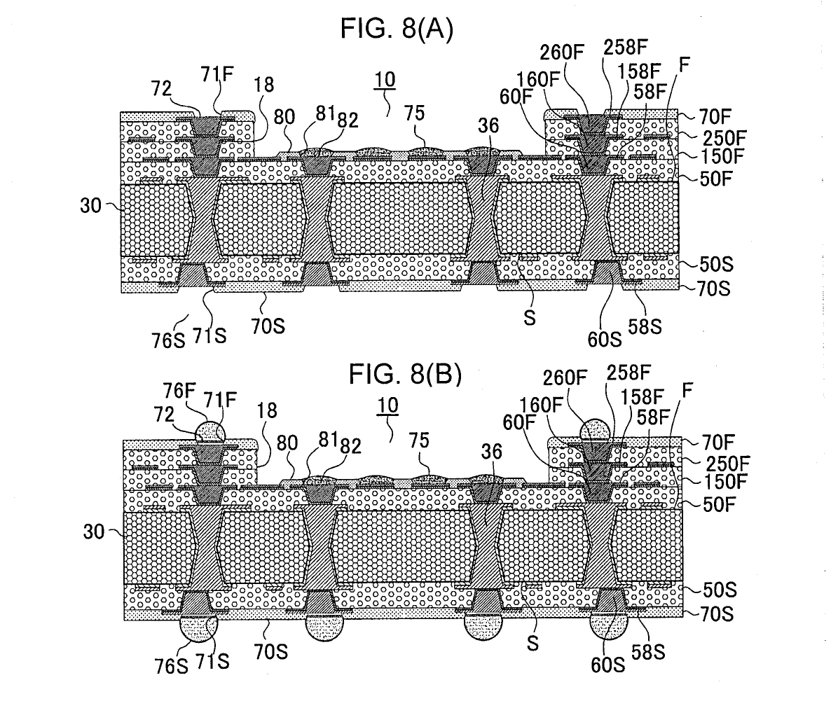

(18) The solder bump 75 is formed on the third pad 82 (FIG. 8(A)). A solder ball is put in place, then using reflow the solder bump (76F) is formed on the first pad (71Fp) exposed via the first opening (71F) of the first solder resist layer (70F) and the solder bump (76S) is formed on the second pad (71Sp) exposed via the second opening (71S) of the second solder resist layer (70S), completing the printed wiring board 10 (FIG. 8(B)).

The electronic component 90 is arranged within the cavity 18 and the terminal 92 of the electronic component is connected to the third pad 82 (FIG. 1).

The superstrate 310, on which the IC chip 900 is mounted, is connected to the printed wiring board 10 via the pad 312 and the solder bump (76F) on the first pad (71F) (FIG. 10). This results in a package-on-package structure.

In the printed wiring board according to the manufacturing method for the first embodiment, after the low-tier resin insulating layers (50F, 50S) have been formed, the mid-tier resin insulating layer (150F) and outermost-tier resin insulating layer (250F) are formed on the first surface. Then, the slit to the laser reception conductor pattern (58FP) is formed using a laser, and the cavity 18 is formed by removing a portion of the peel layer 84 and the outermost-tier resin insulating layer. Across the interior of the cavity 18, the number of interlayer insulating layers in the first build-up layer can be made equal to the number of interlayer insulating layers in the second build-up layer. When the interlayer insulating layers are cured, stress is applied symmetrically, and therefore coplanarity of the cavity bottom is favorable and reliability of the connection between the terminals 92 of the electronic component 90 accommodated therein and the third pads 82 provided to the cavity bottom improves. Moreover, on the exterior of the cavity 18, the number of interlayer insulating layers in the first build-up layer can be made greater than the number of interlayer insulating layers in the second build-up layer. Therefore, the area where the top end of the first surface-side build-up layer (55F) connects with the superstrate side is raised, and connections via the small-diameter solder bumps (76F) with the superstrate 310 can be achieved at a narrow pitch.

The number of layers in the build-up layer is asymmetrical, when a core substrate is exposed in a cavity for installing an electronic component and no resin insulating layer is present on the cavity side, and on the opposite side, two layers of interlayer insulating layers are present. When the interlayer insulating layers are cured, stress is applied asymmetrically, reducing coplanarity (flatness) of the cavity bottom, which is detrimental to reliability of the connection between a terminal of the electronic component accommodated therein and the pad provided to the cavity bottom.

A printed wiring board according to an embodiment of the present invention and a method for manufacturing a printed wiring board according to an embodiment of the present invention have favorable coplanarity of a cavity bottom accommodating an electronic component.

A printed wiring board according to an embodiment of the present invention includes a core substrate having a first surface and a second surface on a side opposite the first surface; a first build-up layer formed on the first surface of the core substrate; a second build-up layer formed on the second surface of the core substrate; a recessed portion for accommodating an electronic component, the recessed portion being formed by removing a portion of the first build-up layer; a first contact pad formed on a front surface of the first build-up layer; a second contact pad formed on a front surface of the second build-up layer; and a third contact pad formed on a bottom surface of the recessed portion. In addition, in an interior portion of the first build-up layer across the recessed portion, the number of interlayer insulating layers in the first build-up layer is set equal to the number of interlayer insulating layers in the second build-up layer, while in an outer portion of the first build-up layer with respect to the recessed portion, the number of interlayer insulating layers in the first build-up layer is greater than the number of interlayer insulating layers in the second build-up layer.

A method for manufacturing a printed wiring board according to an embodiment of the present invention includes forming a build-up layer having the same number of layers on each of a first surface and second surface of a core substrate having the first surface and the second surface on a side opposite the first surface, and additionally, forming a laser reception conductor pattern on a surface of the build-up layer on the first surface along an edge of a recessed portion formation position; providing a peel layer on the recessed portion formation position, and forming a resin insulating layer around a periphery of the peel layer such that the resin insulating layer has an opening corresponding to the peel layer; forming an outermost-tier resin insulating layer on the opening of the resin insulating layer and the resin insulating layer; and forming a slit to the laser reception conductor pattern with a laser and forming a recessed portion by removing a portion of the peel layer and the outermost-tier resin insulating layer.

A printed wiring board according to an embodiment of the present invention has, across the interior of the recessed portion, a number of interlayer insulating layers in the first build-up layer equal to the number of interlayer insulating layers in the second build-up layer. When the number of layers in the build-up layers is symmetrical across the interior of the recessed portion (across the bottom of the recessed portion) and the interlayer insulating layers are cured, stress is applied symmetrically, and therefore coplanarity of the cavity bottom is favorable and reliability of a connection between the terminal of the electronic component accommodated therein and the pad provided to the cavity bottom improves. Moreover, on the exterior of the recessed portion, the number of interlayer insulating layers in the first build-up layer is greater than the number of interlayer insulating layers in the second build-up layer. Therefore, an area where a top end of the first surface-side build-up layer connects with a superstrate side is raised, and a connection with the superstrate can be achieved at a narrow pitch.

In a method for manufacturing a printed wiring board according to an embodiment of the present invention, the build-up layer having the same number of layers is formed on each of the first surface and second surface of the core substrate; the laser reception conductor pattern is formed on the front surface of the build-up layer on the first surface; the peel layer is provided to the recessed portion formation position; the resin insulating layer is formed around the periphery of the peel layer such that the resin insulating layer has an opening corresponding to the peel layer; and the outermost-tier resin insulating layer is formed on the opening of the resin insulating layer and the resin insulating layer. Then, the slit to the laser reception conductor pattern is formed using a laser, and the recessed portion is formed by removing a portion of the peel layer and the outermost-tier resin insulating layer. Across the interior of the recessed portion, the number of interlayer insulating layers in the first build-up layer can be made equal to the number of interlayer insulating layers in the second build-up layer. When the interlayer insulating layers are cured, stress is applied symmetrically, and therefore coplanarity of the cavity bottom is favorable and reliability of the connection between the terminal of the electronic component accommodated therein and the pad provided to the cavity bottom improves. Moreover, on the exterior of the recessed portion, the number of interlayer insulating layers in the first build-up layer can be made greater than the number of interlayer insulating layers in the second build-up layer. Therefore, the area where the top end of the first surface-side build-up layer connects with the superstrate side is raised, and the connection with the superstrate can be achieved at a narrow pitch.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a core substrate;
a first build-up layer formed on a first surface of the core substrate and having a recessed portion configured to accommodate an electronic component;
a second build-up layer formed on a second surface of the core substrate on an opposite side with respect to the first surface of the core substrate; and
a plurality of contact pads comprising a plurality of first contact pads formed on a surface of the first build-up layer, a plurality of second contact pads formed on a surface of the second build-up layer, and a plurality of third contact pads formed in a bottom surface of the recessed portion of the first build-up layer,
wherein the first build-up layer has a plurality of interlayer insulating layers, the second build-up layer has a plurality of interlayer insulating layers, the plurality of interlayer insulating layers in an interior portion of the first build-up layer between the core substrate and the bottom surface of the recessed portion has a number of interlayer insulating layers which is equal to a number of interlayer insulating layers in the second build-up layer, and the plurality of interlayer insulating layers in an exterior portion of the first build-up layer between the core substrate and the surface of the first build-up layer has a number of interlayer insulating layers which is greater than a number of interlayer insulating layers in the second build-up layer.

2. A printed wiring board according to claim 1, wherein the plurality of first contact pads on the surface of the first build-up layer has upper surfaces which are formed in a range of 80 μm to 250 μm higher than upper surfaces of the plurality of third contact pads in the bottom surface of the recessed portion.

3. A printed wiring board according to claim 1, wherein the plurality of interlayer insulating layers in the exterior portion of the first build-up layer has two more interlayer insulating layers than the number of interlayer insulating layers in the second build-up layer.

4. A printed wiring board according to claim 1, wherein the first build-up layer has a conductor pattern formed on the bottom surface of the recessed portion such that the conductor pattern extends along an edge of the recessed portion.

5. A printed wiring board according to claim 1, further comprising:
a first solder resist layer formed on the surface of the first build-up layer and having a plurality of opening portions exposing the plurality of first contact pads, respectively; and
a third solder resist layer formed on the bottom surface of the recessed portion of the first build-up layer and having a plurality of opening portions exposing the plurality of third contact pads, respectively,
wherein the first solder resist layer is formed such that the first solder resist layer has a thickness which is greater than a thickness of the third solder resist layer.

6. A printed wiring board according to claim 1, wherein the plurality of first contact pads is formed on the surface of the first build-up layer such that the first contact pads are positioned to mount a first electronic component, and the plurality of third contact pads is formed on the bottom surface of the recessed portion of the first build-up layer such that the third contact pads are positioned to mount a second electronic component in the recessed portion of the first build-up layer.

7. A printed wiring board according to claim 1, wherein the plurality of first contact pads is formed on the surface of the first build-up layer such that the first contact pads are positioned to mount a first semiconductor component, and the plurality of third contact pads is formed on the bottom surface of the recessed portion of the first build-up layer such that the third contact pads are positioned to mount a second semiconductor component in the recessed portion of the first build-up layer.

8. A printed wiring board according to claim 1, further comprising:
a first solder resist layer formed on the surface of the first build-up layer and having a plurality of opening portions exposing the plurality of first contact pads, respectively; and
a third solder resist layer formed on the bottom surface of the recessed portion of the first build-up layer and having a plurality of opening portions exposing the plurality of third contact pads, respectively.

9. A printed wiring board according to claim 4, wherein the plurality of first contact pads on the surface of the first build-up layer has upper surfaces which are formed in a range of 80 μm to 250 μm higher than upper surfaces of the plurality of third contact pads in the bottom surface of the recessed portion.

10. A printed wiring board according to claim 4, wherein the plurality of interlayer insulating layers in the exterior portion of the first build-up layer has two more interlayer insulating layers than the number of interlayer insulating layers in the second build-up layer.

11. A printed wiring board according to claim 4, further comprising:
a first solder resist layer formed on the surface of the first build-up layer and having a plurality of opening portions exposing the plurality of first contact pads, respectively; and
a third solder resist layer formed on the bottom surface of the recessed portion of the first build-up layer and having a plurality of opening portions exposing the plurality of third contact pads, respectively,
wherein the first solder resist layer is formed such that the first solder resist layer has a thickness which is greater than a thickness of the third solder resist layer.

12. A printed wiring board according to claim 4, wherein the plurality of first contact pads is formed on the surface of the first build-up layer such that the first contact pads are positioned to mount a first electronic component, and the plurality of third contact pads is formed on the bottom surface of the recessed portion of the first build-up layer such that the third contact pads are positioned to mount a second electronic component in the recessed portion of the first build-up layer.

13. A printed wiring board according to claim 4, further comprising:
a first solder resist layer formed on the surface of the first build-up layer and having a plurality of opening portions exposing the plurality of first contact pads, respectively; and
a third solder resist layer formed on the bottom surface of the recessed portion of the first build-up layer and having a plurality of opening portions exposing the plurality of third contact pads, respectively.

14. A package-on-package device, comprising:
a printed wiring board of claim 1, wherein the plurality of first contact pads is formed on the surface of the first build-up layer such that the first contact pads are positioned to mount a first electronic component, and the plurality of third contact pads is formed on the bottom surface of the recessed portion of the first build-up layer such that the third contact pads are positioned to mount a second electronic component in the recessed portion of the first build-up layer.

15. A package-on-package device, comprising:
a printed wiring board of claim 1, wherein the plurality of first contact pads is formed on the surface of the first build-up layer such that the first contact pads are positioned to mount a first semiconductor component, and the plurality of third contact pads is formed on the bottom surface of the recessed portion of the first build-up layer such that the third contact pads are positioned to mount a second semiconductor component in the recessed portion of the first build-up layer.

16. A method for manufacturing a printed wiring board, comprising:
forming a first build-up layer comprising at least one interlayer insulating layer on a first surface of a core substrate;
forming a second build-up layer comprising at least one interlayer insulating layer on a second surface of the core substrate on an opposite side with respect to the first surface of the core substrate such that the second build-up layer has a number of the at least one interlayer insulating layer which is equal to a number of the at least one interlayer insulating layer in the first build-up layer;
forming a laser reception conductor pattern on a surface of the first build-up layer such that the first build-up layer includes the laser reception conductor pattern extending along an edge of a recessed portion formation position;
forming a peel layer on the recessed portion formation position on the first build-up layer such that the first build-up layer includes the peel layer;
forming a resin insulating layer around a periphery of a peel layer such that the first build-up layer includes the resin insulating layer having an opening corresponding to the peel layer;
forming an outermost-tier resin insulating layer on the opening of the resin insulating layer and the resin insulating layer such that the first build-up layer includes the outermost-tier resin insulating layer;
irradiating laser upon the first build-up layer such that a slit reaching to the laser reception conductor pattern is formed; and
removing the peel layer from the first build-up layer such that a recessed portion configured to accommodate an electronic component is formed in the first build-up layer.

17. A method for manufacturing a printed wiring board according to claim 16, further comprising:
forming a plurality of contact pads on the surface of the first build-up layer in a process of the forming of the laser reception conductor pattern such that the plurality of contact pads is formed in the recessed portion formation position.

18. A method for manufacturing a printed wiring board according to claim 16, further comprising:
forming a plurality of contact pads on the surface of the first build-up layer in a process of the forming of the laser reception conductor pattern such that the plurality of contact pads is formed in the recessed portion formation position; and
forming a solder resist layer on the plurality of contact pads in the recessed portion formation position prior to the forming of the peel layer.

19. A method for manufacturing a printed wiring board according to claim 16, further comprising:
forming a plurality of contact pads on the surface of the first build-up layer in a process of the forming of the laser reception conductor pattern such that the plurality of contact pads is formed in the recessed portion formation position,
wherein the peel layer is formed on the plurality of contact pads.

20. A method for manufacturing a printed wiring board according to claim 16, further comprising:
forming a plurality of contact pads on the surface of the first build-up layer in a process of the forming of the laser reception conductor pattern such that the plurality of contact pads is formed in the recessed portion formation position; and
forming a solder resist layer having a plurality of opening portions exposing the plurality of contact pads, respectively, such that the solder resist layer is formed on the plurality of contact pads in the recessed portion formation position prior to the forming of the peel layer.
